(19) United States
(12) Patent Application Publication
(10) Pub. No.: US 2024/0260376 A1
(43) Pub. Date: Aug. 1, 2024

(54) DISPLAY DEVICE AND ELECTRONIC APPARATUS

(71) Applicant: SEIKO EPSON CORPORATION, Tokyo (JP)

(72) Inventor: Takumi KODAMA, Chino-shi (JP)

(73) Assignee: SEIKO EPSON CORPORATION, Tokyo (JP)

(21) Appl. No.: 18/424,846

(22) Filed: Jan. 28, 2024

(30) Foreign Application Priority Data
Jan. 30, 2023 (JP) 2023-011627

(51) Int. Cl. H10K 59/38; H10K 59/127; H10K 59/80

(52) U.S. Cl. CPC H10K 59/38; H10K 59/1275; H10K 59/8792

(57) ABSTRACT

A display device including a first substrate and a second substrate bonded to each other via an adhesive is provided. The first substrate includes a support substrate including a substrate surface at a side facing the second substrate, a plurality of light-emitting elements provided at a substrate surface side of the support substrate, a first color filter and a second color filter respectively provided at a second substrate side of a first light-emitting element and a second light-emitting element of the light-emitting elements, a light-shielding layer provided at the substrate surface side of the support substrate, surrounding the light-emitting elements, and including a layer made of the same material as the first color filter and a layer made of the same material as the second color filter, and a wall portion provided at a side of the light-shielding layer opposite to the support substrate and surrounding the light-emitting elements.

The present application is based on, and claims priority from JP Application Serial Number 2023-011627, filed Jan. 30, 2023, the disclosure of which is hereby incorporated by reference herein in its entirety.

### BACKGROUND

### 1. Technical Field

The present disclosure relates to a display device and an electronic apparatus.

### 2. Related Art

There has been known a display device including a light-emitting element such as an organic electroluminescence (EL) element.

For example, JP-A-2012-99313 describes an organic EL display device in which, at an element substrate including a display region in which pixels including organic EL layers are formed in a matrix and a terminal portion, a sealing substrate is arranged to cover the display region via an adhesive.

In the organic EL device described above, the sealing substrate may be arranged without generating a height difference. When the sealing substrate has a height difference, optical unevenness is caused.

### SUMMARY

A display device according to one aspect of the present disclosure includes a first substrate, and a second substrate arranged facing the first substrate and having a light-transmitting property, wherein the first substrate includes a support substrate including a substrate surface being a surface at a side facing the second substrate, a plurality of light-emitting elements provided at a substrate surface side of the support substrate, a first color filter provided at a second substrate side of a first light-emitting element of the plurality of light-emitting elements, a second color filter provided at a second substrate side of a second light-emitting element of the plurality of light-emitting elements and having a color different from that of the first color filter, a light-shielding layer provided at the substrate surface side of the support substrate, surrounding the plurality of light-emitting elements in a plan view, and including a first layer made of the same material as that of the first color filter and a second layer made of the same material as that of the second color filter, and a wall portion provided at a side of the light-shielding layer opposite to the support substrate and surrounding the plurality of light-emitting elements in the plan view, an adhesive is provided at an inner side of the wall portion in the plan view, and the second substrate is bonded to the first substrate via the adhesive.

An electronic apparatus according to one aspect of the present disclosure includes the display device of the one aspect.

### BRIEF DESCRIPTION OF THE DRAWINGS

FIG. 1 is a plan view schematically illustrating a display device according to the present embodiment.

FIG. 2 is an equivalent circuit diagram illustrating an electrical configuration of the display device according to the present embodiment.

FIG. 3 is a plan view for describing a subpixel of the display device according to the present embodiment.

FIG. 4 is a cross-sectional view schematically illustrating the display device according to the present embodiment.

FIG. 5 is a cross-sectional view schematically illustrating the display device according to the present embodiment.

FIG. 6 is a plan view schematically illustrating a display device according to a modification example of the present embodiment.

FIG. 7 is a perspective view schematically illustrating a head-mounted display according to the present embodiment.

FIG. 8 is a diagram schematically illustrating an image forming device and a light-guiding device of the head-mounted display according to the present embodiment.

### DESCRIPTION OF EMBODIMENTS

A preferred embodiment of the present disclosure is described below in detail with reference to the drawings. Note that the embodiment described below do not unduly limit the content of the present disclosure described in the claims. In addition, not all the configurations described below are essential constituent elements of the present disclosure.

### 1. Display Device

### 1.1. Overall Configuration

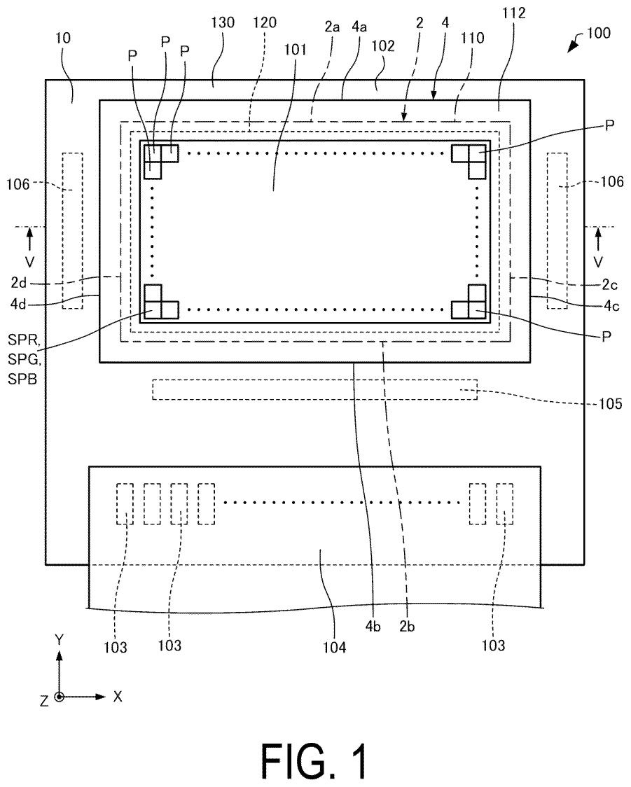

First, a display device according to the present embodiment is described with reference to the drawings. FIG. 1 is a plan view schematically illustrating a display device 100 according to the present embodiment. Note that an X-axis, a Y-axis, and a Z-axis are illustrated in FIG. 1 as three axes orthogonal to each other.

As illustrated in FIG. 1, the display device 100 includes an element substrate 10 and a counter substrate 110. The element substrate 10 and the counter substrate 110 are arranged facing each other. Note that for the sake of convenience, in FIG. 1, illustration is given through the counter substrate 110.

The element substrate 10 includes a display region 101 in which a plurality of pixels P are arranged in a matrix, and a non-display region 102 which is a peripheral region further outward of the display region 101. The non-display region 102 surrounds the display region 101 in plan view from the Z-axis direction (hereinafter also simply referred to as “in plan view”).

The plurality of pixels P are arranged, for example, in a matrix in the X-axis direction and the Y-axis direction. The pixel P includes three subpixels SP. The three subpixels SP are the red subpixel SPR that emits red light, the green subpixel SPG that emits green light, and the blue subpixel SPB that emits blue light. The display device 100 provides a full-color display with the pixel P that includes the subpixels SPR, SPG, and SPB and serves as a display unit.

An area of the element substrate 10 is larger than an area of the counter substrate 110 in plan view. In the illustrated example, the shape of the element substrate 10 is a rectangular shape. In a region that does not overlap with the counter substrate 110 of the element substrate 10 in plan view, a plurality of external coupling terminals 103 are provided. The counter substrate 110 is arranged so that the external coupling terminals 103 are exposed. In the illustrated example, the plurality of external coupling terminals 103 are arrayed in the X-axis direction. A flexible printed circuit (FPC) 104 is mounted at the external coupling terminals 103. The FPC 104 is electrically coupled to an external driving circuit that supplies a control signal, power, and the like for display on the display region 101.

The non-display region 102 is provided with a data line driving circuit 105 and scanning line driving circuits 106. The data line driving circuit 105 is provided in the −Y-axis direction of the display region 101. One of the two scanning line driving circuits 106 is provided in the +X-axis direction of the display region 101. The other of the two scanning line driving circuits 106 is provided in the −X-axis direction of the display region 101.

### 1.2. Electrical Configuration

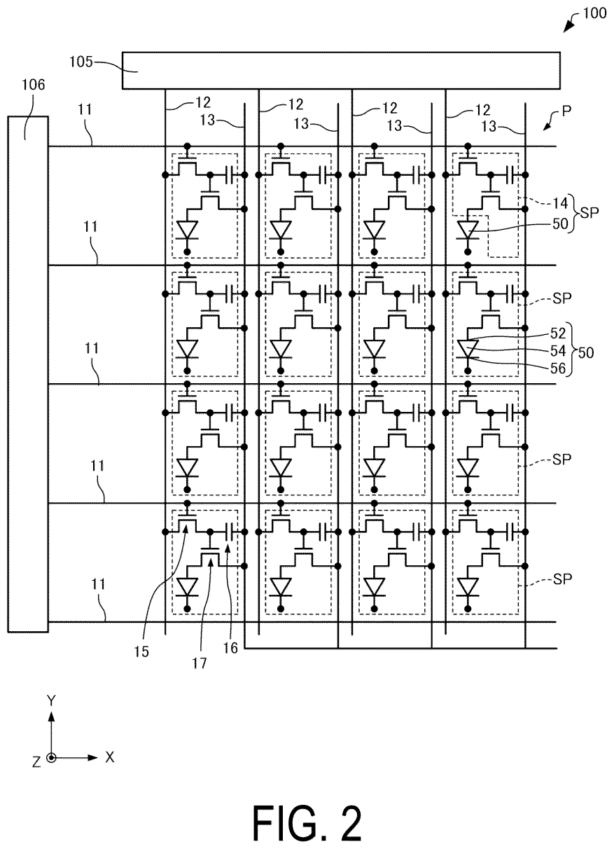

FIG. 2 is an equivalent circuit diagram illustrating an electrical configuration of the display device 100.

As illustrated in FIG. 2, for example, the display device 100 includes scanning lines 11 and data lines 12, which intersect with each other, and power lines 13. The scanning lines 11 are electrically coupled to the scanning line driving circuit 106. The data lines 12 are electrically coupled to the data line driving circuit 105. The subpixel SP is provided in a region partitioned by the scanning line 11 and the data line 12.

For example, the subpixel SP includes an organic EL element 50 and a pixel circuit 14 that controls the driving of the organic EL element 50.

The organic EL element 50 includes a pixel electrode 52, a light-emitting functional layer 54, and a counter electrode 56. The pixel electrode 52 serves as a positive electrode that injects holes into the light-emitting functional layer 54. The counter electrode 56 serves as a negative electrode that injects electrons into the light-emitting functional layer 54. In the light-emitting functional layer 54, excitons are formed by the injected holes and electrons, and when the excitons decay, some of the resulting energy is radiated as fluorescence or phosphorescence.

For example, the pixel circuit 14 includes a switching transistor 15, a storage capacitor 16, and a driving transistor 17. Each of the transistors 15 and 17 may be an n-type channel transistor or a p-type channel transistor.

The gate of the switching transistor 15 is electrically coupled to the scanning line 11. The source of the switching transistor 15 is electrically coupled to the data line 12. The drain of the switching transistor 15 is electrically coupled to the gate of the driving transistor 17.

The drain of the driving transistor 17 is electrically coupled to the pixel electrode 52 of the organic EL element 50. The source of the driving transistor 17 is electrically coupled to the power line 13. The storage capacitor 16 is electrically coupled between the gate of the driving transistor 17 and the power line 13.

When the switching transistor 15 is driven by the scanning line 11 under a control signal supplied from the scanning line driving circuit 106 and is turned to an ON state, a potential based on an image signal supplied from the data line 12 is stored in the storage capacitor 16 via the switching transistor 15. The ON/OFF state of the driving transistor 17 is determined in accordance with the potential of the storage capacitor 16, in other words, the gate potential of the driving transistor 17. Further, when the driving transistor 17 is turned to the ON state, an amount of current based on the gate potential flows to the organic EL element 50 from the power line 13 via the driving transistor 17. The organic EL element 50 emits light at a luminance based on the amount of current flowing to the light-emitting functional layer 54.

Note that the configuration of the pixel circuit 14 is not limited to include the two transistors 15 and 17. For example, the pixel circuit 14 may further include a transistor for controlling the current flowing to the organic EL element 50.

### 1.3. Arrangement of Subpixels

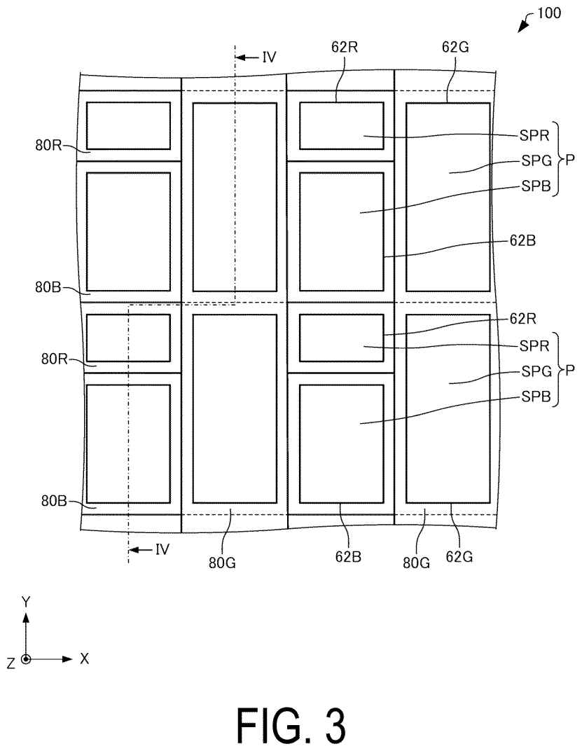

FIG. 3 is a plan view for describing the subpixels SPR, SPG, and SPB of the display device 100.

Note that in the following description, the organic EL element 50 of the red subpixel SPR is also referred to as an “organic EL element 50R”. The organic EL element 50 of the green subpixel SPG is also referred to as an “organic EL element 50G”. The organic EL element 50 of the blue subpixel SPB is also referred to as an “organic EL element 50B”.

As illustrated in FIG. 3, the plurality of pixels P are arranged in a matrix in the X-axis direction and the Y-axis direction. In the illustrated example, in one pixel P, the red subpixel SPR and the blue subpixel SPB are adjacent to each other in the Y-axis direction. The green subpixel SPG is adjacent to the red subpixel SPR and the blue subpixel SPB in the X-axis direction.

A shape of a light-emitting region of each of the subpixels SPR, SPG, and SPB is determined by an insulating layer that defines a region where the pixel electrode 52 and the light-emitting functional layer 54 of the organic EL element 50 are in contact with each other. The light-emitting region is a region that overlaps with an opening portion formed in the insulating layer in plan view. As the opening portion, an opening portion 62R is formed in the red subpixel SPR. An opening portion 62G is formed in the green subpixel SPG. An opening portion 62B is formed in the blue subpixel SPB.

For example, the shape of each of the opening portions 62R, 62G, and 62B is a rectangular shape in plan view. In the illustrated example, an area of the opening portion 62G is larger than an area of the opening portion 62B. The area of the opening portion 62B is larger than an area of the opening portion 62R.

The red subpixel SPR includes a red color filter 80R. The opening portion 62R is provided at the inner side of the outer edge of the red color filter 80R in plan view.

The green subpixel SPG includes a green color filter 80G. The opening portion 62G is provided at the inner side of the outer edge of the green color filter 80G in plan view. In the pixels P adjacent to each other in the Y-axis direction, the green color filter 80G of one pixel P and the green color filter 80G of the other pixel P are continuously provided in an integrated manner. Thus, the green color filters 80G are provided in a stripe shape in plan view.

The blue subpixel SPB includes a blue color filter 80B. The opening portion 62B is provided at the inner side of the outer edge of the blue color filter 80B in plan view.

The luminance of the color light emitted from each of the subpixels SPR, SPG, and SPB depends on the size of each of the opening portions 62R, 62G, and 62B and a transmittance of each of the color filters 80R, 80G, and 80B that overlap with the opening portions 62R, 62G, and 62B.

### 1.4. Cross-Sectional Structure of Subpixel

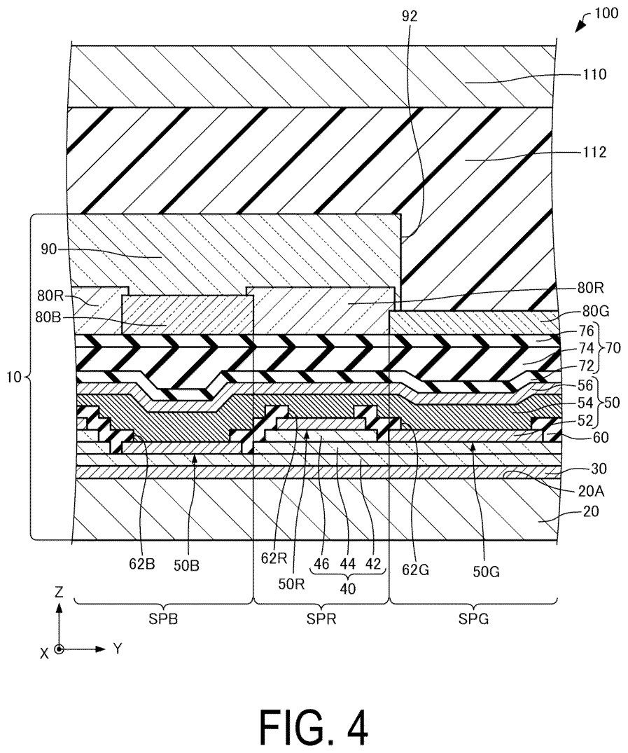

FIG. 4 is a cross-sectional view taken along line IV-IV of FIG. 3, schematically illustrating the display device 100.

As illustrated in FIG. 4, the display device 100 includes the element substrate 10, the counter substrate 110, and an adhesive 112.

For example, the element substrate 10 includes a support substrate 20, a reflective layer 30, a light-transmitting layer 40, the organic EL element 50, an insulating layer 60, a sealing layer 70, the color filters 80R, 80G, and 80B, and an overcoat layer 90. The element substrate 10 constitutes the subpixels SPR, SPG, and SPB.

The support substrate 20 is a semiconductor substrate such as silicon, for example. In the illustrated example, a vertical line of the top surface of the support substrate 20, in other words, a substrate surface 20A of the support substrate 20 at the counter substrate 110 side is parallel to the Z-axis. The substrate surface 20A is a surface at the side facing the counter substrate 110. The support substrate 20 is provided with the scanning lines 11, the data lines 12, the power lines 13, the pixel circuits 14, the data line driving circuit 105, and the scanning line driving circuits 106 that are described above. Note that the support substrate 20 is not limited to a semiconductor substrate, and may instead be a substrate constituted by quartz, glass, or the like, for example.

The reflective layer 30 is provided at the support substrate 20. The reflective layer 30 is provided between the support substrate 20 and the light-transmitting layer 40. The reflective layer 30 is continuous in the subpixels SPB, SPR, and SPG. The material of the reflective layer 30 is aluminum, silver, or an alloy including these metals. The reflective layer 30 reflects the light emitted from the organic EL element 50 to the counter substrate 110 side.

The light-transmitting layer 40 is provided at the reflective layer 30. The light-transmitting layer 40 is provided between the reflective layer 30 and the organic EL element 50. The light-transmitting layer 40 has a light-transmitting property with respect to the light generated at the light-emitting functional layer 54 of the organic EL element 50. The light-transmitting layer 40 is a silicon oxide layer, for example. For example, the light-transmitting layer 40 includes the first insulating layer 42, a second insulating layer 44, and a third insulating layer 46.

The first insulating layer 42 of the light-transmitting layer 40 is provided at the reflective layer 30. The first insulating layer 42 is continuous in the subpixels SPB, SPR, and SPG. The second insulating layer 44 is provided at the first insulating layer 42. The second insulating layer 44 is continuous in the subpixels SPR and SPG. The third insulating layer 46 is provided at the second insulating layer 44. In the illustrated example, the light-transmitting layer 40 of the red subpixel SPR is constituted by the insulating layers 42, 44, and 46. The light-transmitting layer 40 of the green subpixel SPG is constituted by the insulating layers 42 and 44. The light-transmitting layer 40 of the blue subpixel SPB is constituted by the first insulating layer 42. The thickness of the light-transmitting layer 40 of the red subpixel SPR is larger than the thickness of the light-transmitting layer 40 of the green subpixel SPG. The thickness of the light-transmitting layer 40 of the green subpixel SPG is larger than the thickness of the light-transmitting layer 40 of the blue subpixel SPB.

The organic EL element 50 is provided at the light-transmitting layer 40. The organic EL element 50 is provided to the support substrate 20 on the substrate surface 20A. The organic EL element 50 is provided between the light-transmitting layer 40 and the sealing layer 70. The organic EL element 50 is provided to the support substrate 20 via the light-transmitting layer 40 and the reflective layer 30. The organic EL element 50 is an organic light-emitting diode (OLED), for example. The organic EL element 50 includes the pixel electrode 52, the light-emitting functional layer 54, and the counter electrode 56.

The pixel electrode 52 is provided at the light-transmitting layer 40. The pixel electrode 52 is provided between the light-transmitting layer 40 and the light-emitting functional layer 54. The pixel electrode 52 is provided to each of the subpixels SPR, SPG, and SPB. The pixel electrode 52 is not continuous in the subpixels SPR, SPG, and SPB. The pixel electrode 52 has a light-transmitting property with respect to the light generated at the light-emitting functional layer 54. As the pixel electrode 52, for example, a transparent electrode made of indium tin oxide (ITO) is used.

The light-emitting functional layer 54 is provided at the pixel electrode 52. The light-emitting functional layer 54 is provided between the pixel electrode 52 and the counter electrode 56. The light-emitting functional layer 54 is continuous in the subpixels SPR, SPG, and SPB. For example, the light-emitting functional layer 54 covers the entire region of the display region 101 illustrated in FIG. 1. The light-emitting functional layer 54 includes, for example, a hole injection layer, a hole transport layer, an organic light-emitting layer, an electron transport layer, and the like, which are layered in the stated order in the Z-axis direction. The organic light-emitting layer generates light in a wavelength range from blue to red, for example. The organic light-emitting layer generates white light, for example.

As illustrated in FIG. 4, the counter electrode 56 is provided at the light-emitting functional layer 54. The counter electrode 56 is provided between the light-emitting functional layer 54 and the sealing layer 70. The counter electrode 56 is continuous in the subpixels SPR, SPG, and SPB. The material of the counter electrode 56 is an alloy of magnesium and silver, for example.

The counter electrode 56, the light-transmitting layer 40, and the reflective layer 30 constitute an optical resonance structure. The light generated at the light-emitting functional layer 54 is repeatedly reflected between the reflective layer 30 and the counter electrode 56, and the intensity of the light having a specific wavelength corresponding to the optical distance between the reflective layer 30 and the counter electrode 56 is amplified. Further, the organic EL elements 50R, 50B, and 50G emits light having specific wavelengths. Specifically, the organic EL element 50R extracts the red light from the white light, and emits the red light. The organic EL element 50G extracts the green light from the white light, and emits the green light. The organic EL element 50B extracts the blue light from the white light, and emits the blue light.

The insulating layer 60 is provided at the pixel electrode 52 and the light-transmitting layer 40. The insulating layer 60 is continuous in the subpixels SPR, SPG, and SPB. As described above, the opening portion 62R is formed in the insulating layer 60 of the red subpixel SPR. The opening portion 62G is formed in the insulating layer 60 of the green subpixel SPG. The opening portion 62B is formed in the insulating layer 60 of the blue subpixel SPB. The opening portions 62R, 62G, and 62B extend through the insulating layer 60. The light-emitting regions of the organic EL elements 50R, 50G, and 50B are regions that overlap with the opening portions 62R, 62G, and 62B in plan view. In the regions where the insulating layer 60 is provided, the supply of holes from the pixel electrodes 52 to the light-emitting functional layer 54 is suppressed, and thus light emission from the light-emitting functional layer 54 is suppressed.

The sealing layer 70 is provided at the counter electrode 56. The sealing layer 70 is provided between the counter electrode 56, and the color filters 80R, 80G, and 80B. For example, the sealing layer 70 includes a first inorganic layer 72, an organic layer 74, and a second inorganic layer 76.

The first inorganic layer 72 of the sealing layer 70 is provided at the counter electrode 56. The second inorganic layer 76 is provided at the organic layer 74. The inorganic layers 72 and 76 are, for example, a silicon oxide layer, a silicon nitride layer, a silicon oxynitride layer, an aluminum oxide layer, or the like. The inorganic layers 72 and 76 suppress entry of moisture and oxidation into the light-emitting functional layer 54.

The organic layer 74 of the sealing layer 70 is provided at the first inorganic layer 72. The organic layer 74 is provided between the first inorganic layer 72 and the second inorganic layer 76. The material of the organic layer 74 is a heat- or ultraviolet light-curing epoxy resin, an acrylic resin, a urethane resin, a silicone resin, or the like. The thickness of the organic layer 74 is larger than the thickness of the inorganic layers 72 and 76. The organic layer 74 improves planarity of the top surface of the sealing layer 70.

The color filters 80R, 80G, and 80B are formed at the sealing layer 70. The color filters 80R, 80G, and 80B are provided between the sealing layer 70 and the counter substrate 110.

The red color filter 80R is provided at the counter substrate 110 side of the organic EL element 50R. The red color filter 80R overlaps with the organic EL element 50R in plan view. The red color filter 80R overlaps with the opening portion 62R. The red color filter 80R transmits the red light. The red color filter 80R improves color purity of the red light emitted from the organic EL element 50R. The material of the red color filter 80R is a red color resist.

The green color filter 80G is provided at the counter substrate 110 side of the organic EL element 50G. The green color filter 80G overlaps with the organic EL element 50G in plan view. The green color filter 80G overlaps with the opening portion 62G. The green color filter 80G transmits the green light. The green color filter 80G improves color purity of the green light emitted from the organic EL element 50G. The material of the green color filter 80G is a green color resist.

The blue color filter 80B is provided at the counter substrate 110 side of the organic EL element 50B. The blue color filter 80B overlaps with the organic EL element 50B in plan view. The blue color filter 80B overlaps with the opening portion 62B. The blue color filter 80B transmits the blue light. The blue color filter 80B improves color purity of the blue light emitted from the organic EL element 50B. The material of the blue color filter 80B is a blue color resist.

The color filters 80R, 80G, and 80B are formed to partially overlap with the adjacent color filters 80R, 80G, and 80B. For example, the color filters 80R, 80G, and 80B are formed by first applying photosensitive resin materials containing color materials of the respective colors through a method such as spin coating to form a photosensitive resin layer, and then exposing and developing the photosensitive resin layer using photolithography. In the illustrated example, the color filters 80G 80B, and 80R are formed in the stated order. Thus, the edge portion of the green color filter 80G in the X-axis direction is covered with the edge portions of the color filters 80R and 80B. The edge portion of the blue color filter 80B in the Y-axis direction is covered with the edge portion of the red color filter 80R.

The thicknesses of the color filters 80R, 80G, and 80B are different from each other. In the illustrated example, the thickness of the red color filter 80R is larger than the thickness of the blue color filter 80B. The thickness of the blue color filter 80B is larger than the thickness of the green color filter 80G.

The overcoat layer 90 is provided at the color filters 80R and 80B that are repeatedly arranged to be adjacent to each other in the Y-axis direction. Moreover, the overcoat layer 90 covers the edge portion of the green color filter 80G. The overcoat layer 90 does not cover portions other than the edge portion of the green color filter 80G. With the overcoat layer 90, a groove 92 is formed along the Y-axis direction in which the green color filter 80G extends. The top surface of the overcoat layer 90 is planar, for example. The top surface of the green color filter 80G that defines the bottom surface of the groove 92 is planar. The overcoat layer 90 is a photosensitive resin layer having a light-transmitting property, for example.

The counter substrate 110 is bonded to the element substrate 10 via the adhesive 112. The counter substrate 110 is arranged facing the element substrate 10. The counter substrate 110 has a light-transmitting property with respect to the light emitted from the organic EL element 50. For example, the counter substrate 110 is a quartz substrate, a glass substrate, or the like. The counter substrate 110 has a function of protecting the organic EL element 50 from damage. The display device 100 adopts a top-emission system in which the light emitted from the organic EL element 50 exits from the counter substrate 110 side.

The adhesive 112 bonds the element substrate 10 and the counter substrate 110 to each other. The adhesive 112 has a light-transmitting property with respect to the light emitted from the organic EL element 50. The material of the adhesive 112 is an epoxy resin, an acrylic resin, or the like, for example.

The adhesive 112 spreads along the plurality of grooves 92 extending in the Y-axis direction. With this, the element substrate 10 and the counter substrate 110 are bonded to each other. The bottom surface the groove 92 does not include a step. Thus, foams are less likely to be generated in the adhesive 112. Moreover, application unevenness of the adhesive 112 is less likely to be caused, as compared to a case in which an overcoat layer is not provided and a step is generated due to a thickness difference of the three color filters.

For example, the display device 100 is manufactured by using a known semiconductor manufacturing process.

### 1.5. Light-Shielding Layer and Wall Portion

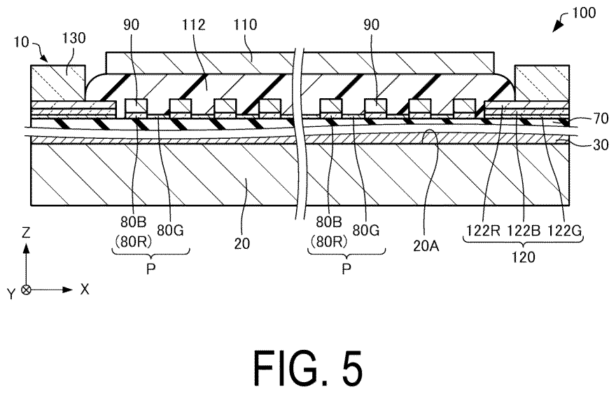

FIG. 5 is a cross-sectional view taken along line V-V of FIG. 1, schematically illustrating the display device 100. Note that in FIG. 5, for the sake of convenience, the element substrate 10 is illustrated in a simplified manner.

As illustrated in FIG. 5, the element substrate 10 of the display device 100 includes a light-shielding layer 120 and a wall portion 130.

The light-shielding layer 120 is provided at the substrate surface 20A side of the support substrate 20. For example, the light-shielding layer 120 is provided to the support substrate 20 via the sealing layer 70 and the like. For example, the light-shielding layer 120 is provided at the sealing layer 70. For example, the light-shielding layer 120 includes a first layer 122G, a second layer 122B, and a third layer 122R.

The first layer 122G of the light-shielding layer 120 is made of the same material as that of the green color filter 80G. The thickness of the first layer 122G and the thickness of the green color filter 80G are the same, for example. The first layer 122G is formed in the step of forming the green color filter 80G.

The second layer 122B of the light-shielding layer 120 is provided at the first layer 122G. The second layer 122B is provided between the first layer 122G and the third layer 122R. The second layer 122B is made of the same material as that of the blue color filter 80B. The thickness of the second layer 122B and the thickness of the blue color filter 80B are the same, for example. The second layer 122B is formed in the step of forming the blue color filter 80B.

The third layer 122R of the light-shielding layer 120 is provided at the second layer 122B. The third layer 122R is provided between the second layer 122B and the wall portion 130. The third layer 122R is made of the same material as that of the red color filter 80R. The thickness of the third layer 122R and the thickness of the red color filter 80R are the same, for example. The third layer 122R is formed in the step of forming the red color filter 80R.

Note that the order of layering of the first layer 122G, the second layer 122B, and the third layer 122R is not particularly limited. For example, when the green color filter 80G, the blue color filter 80B, and the red color filter 80R are formed in the stated order, the first layer 122G, the second layer 122B, and the third layer 122R are layered in the stated order as illustrated in FIG. 5.

As illustrated in FIG. 1, the light-shielding layer 120 surrounds the organic EL elements 50 in plan view. The light-shielding layer 120 surrounds the display region 101 in plan view. In FIG. 1, the inner edge of the light-shielding layer 120 is indicated with the two-dot chain line. The light-shielding layer 120 is provided to the non-display region 102.

The light-shielding layer 120 helps prevent light emitted from the organic EL element 50 from being reflected at another member to affect the organic EL element 50. Moreover, the light-shielding layer 120 helps prevent the light emitted from the organic EL element 50 from entering the data line driving circuit 105 and the scanning line driving circuits 106 to destabilize an operation of the transistor or the like.

As illustrated in FIG. 5, the wall portion 130 is provided at the light-shielding layer 120. The wall portion 130 is provided at a side of the light-shielding layer 120 opposite to the support substrate 20. The wall portion 130 is provided at the third layer 122R. In the illustrated example, the position of the top surface of the wall portion 130 is positioned in the +Z-axis direction with respect to the position of the top surface of the adhesive 112. Note that although omitted in illustration, the position of the top surface of the wall portion 130 may be positioned in the +Z-axis direction with respect to the position of the top surface of the counter substrate 110.

For example, the wall portion 130 has a light-transmitting property with respect to the light emitted from the organic EL element 50. The material of the wall portion 130 is the same material as that of the overcoat layer 90, for example. This can help prevent increase in the number of types of materials constituting the display device 100. As a result, for example, cost reduction can be achieved. The wall portion 130 may be formed in the step of forming the overcoat layer 90, or may be formed in a step different from the step of forming the overcoat layer 90.

As illustrated in FIG. 1, the wall portion 130 surrounds the plurality of organic EL elements 50 in plan view. The wall portion 130 surrounds the display region 101 in plan view. The light-shielding layer 120 includes a region that does not overlap with the wall portion 130 in plan view. The adhesive 112 is provided at the inner side of the wall portion 130 in plan view. In the example illustrated in FIG. 5, the adhesive 112 is in contact with the top surface of the light-shielding layer 120 and the side surface of the wall portion 130. For example, the wall portion 130 is provided to the entire region other than the region overlapping with the adhesive 112 and the region overlapping with the external coupling terminals 103 in plan view. Thus, a step due to the wall portion 130 can be suppressed.

The wall portion 130 surrounds the counter substrate 110 in plan view. The counter substrate 110 is provided at the inner side of the wall portion 130 in plan view. In the example illustrated in FIG. 1, the shape of the counter substrate 110 is a rectangular shape. An outer edge 2 of the counter substrate 110 includes long sides 2a and 2b and short sides 2c and 2d in plan view. In the illustrated example, the long side 2a is a side in the +Y-axis direction. The long side 2b is a side in the −Y-axis direction. The short side 2c is a side in the +X-axis direction. The short side 2d is a side in the −X-axis direction.

An inner edge 4 of the wall portion 130 includes sides 4a and 4b parallel to the long sides 2a and 2b and sides 4c and 4d parallel to the short sides 2c and 2d. In the illustrated example, the side 4a is a side in the +Y-axis direction. The side 4b is a side in the −Y-axis direction. The side 4c is a side in the +X-axis direction. The side 4d is a side in the −X-axis direction. The side 4a faces the long side 2a. In other words, the side surface of the wall portion 130 that defines the side 4a faces the side surface of the counter substrate 110 that defines the long side 2a. The side 4b faces the long side 2b. The side 4c faces the short side 2c. The side 4d faces the short side 2d. The distance between the long side 2a and the side 4a, the distance between the long side 2b and the side 4b, the distance between the short side 2c and the side 4c, and the distance between the short side 2d and the side 4d are the same, for example.

### 1.6. Effects

The display device 100 includes the element substrate 10 being a first substrate, and the counter substrate 110 being a second substrate that is arranged facing the element substrate 10 and that has a light-transmitting property. The element substrate 10 includes the support substrate 20 including the substrate surface 20A being a surface at the side facing the counter substrate 110 and the organic EL elements 50 being a plurality of light-emitting elements provided at the substrate surface 20A of the support substrate 20. Moreover, the element substrate 10 includes the green color filter 80G and the blue color filter 80B. The green color filter 80G is a first color filter provided at the counter substrate 110 side of the organic EL element 50G, the organic EL element 50G being a first light-emitting element of the plurality of organic EL elements 50. The blue color filter 80B is a second color filter provided at the counter substrate 110 side of the organic EL element 50B, the organic EL element 50B being a second light-emitting element of the plurality of organic EL elements 50, and has a color different from that of the green color filter 80G. Moreover, the element substrate 10 includes the light-shielding layer 120 and the wall portion 130. The light-shielding layer 120 includes the first layer 122G provided at the substrate surface 20A of the support substrate 20, surrounding the plurality of organic EL elements 50 in plan view, and made of the same material as that of the green color filter 80G, and the second layer 122B made of the same material as that of the blue color filter 80B. The wall portion 130 is provided at a side of the light-shielding layer 120 opposite to the support substrate 20, and surrounds the plurality of organic EL elements 50 in plan view. The adhesive 112 is provided at the inner side of the wall portion 130 in plan view, and the counter substrate 110 is bonded to the element substrate 10 via the adhesive 112.

Thus, in the display device 100, the wall portion 130 can be arranged at a higher position, as compared to a case in which the wall portion 130 is not provided at the light-shielding layer 120. In the example illustrated in FIG. 5, the wall portion 130 can be arranged further in the +Z-axis direction. With this, even when the counter substrate 110 is pressed down, the adhesive 112 is less likely to overflow from the wall portion 130. Therefore, a height difference of the counter substrate 110 can be reduced. For example, a height difference of the counter substrate 110 with respect to the sealing layer 70 can be reduced. As a result, optical unevenness can be reduced.

Moreover, in the display device 100, the light-shielding layer 120 includes the first layer 122G made of the same material as that of the green color filter 80G and the second layer 122B made of the same material as that of the blue color filter 80B. Thus, planarity of the top surface is enhanced. Thus, in the display device 100, the wall portion 130 can be arranged at a planar place. With this, the wall portion 130 can more reliably stem the adhesive 112.

In the display device 100, the counter substrate 110 is provided at the inner side of the wall portion 130 in plan view. Thus, in the display device 100, a height difference of the counter substrate 110 can be further reduced.

In the display device 100, in plan view, the outer edge 2 of the counter substrate 110 includes the long side 2a being a first side, and the inner edge 4 of the wall portion 130 includes the side 4a being a second side that is parallel to the long side 2a and faces the long side 2a. Thus, in the display device 100, the amount of the adhesive 112 between the long side 2a and the side 4a can be constant in the extension direction of the long side 2a. With this, a height difference of the counter substrate 110 can be further reduced. Moreover, the distance between the long side 2a and the side 4a, the distance between the long side 2b and the side 4b, the distance between the short side 2c and the side 4c, and the distance between the short side 2d and the side 4d are the same. Thus, a height difference of the counter substrate 110 can be further reduced.

In the display device 100, the wall portion 130 has a light-transmitting property. Thus, in the display device 100, the light that is emitted from the organic EL element 50 and enters the wall portion 130 can be transmitted to the outside of the wall portion 130. This can help prevent the light emitted from the organic EL element 50 from being reflected by the wall portion 130 to affect the organic EL element 50 or the like.

Note that the wall portion 130 may have a light-shielding property with respect to the light emitted from the organic EL element 50. When the wall portion 130 has a light-shielding property, the wall portion 130 is capable of absorbing the light, which is emitted from the organic EL element 50 and enters the wall portion 130, at the wall portion 130. This can help prevent the light emitted from the organic EL element 50 from being reflected by the wall portion 130 to affect the organic EL element 50 or the like. When the wall portion 130 has a light-shielding property, the wall portion 130 may be constituted by a black matrix.

In the display device 100, the element substrate 10 includes the red color filter 80R. The red color filter 80R is a third color filter provided at the counter substrate 110 side of the organic EL element 50R, the organic EL element 50R being a third light-emitting element of the plurality of organic EL elements 50, and has a color different from those of the green color filter 80G and the blue color filter 80B. The light-shielding layer 120 includes the third layer 122R made of the same material as that of the red color filter 80R. Thus, in the display device 100, the wall portion 130 can be arranged at a higher position.

### 2. Modification Example of Display Device

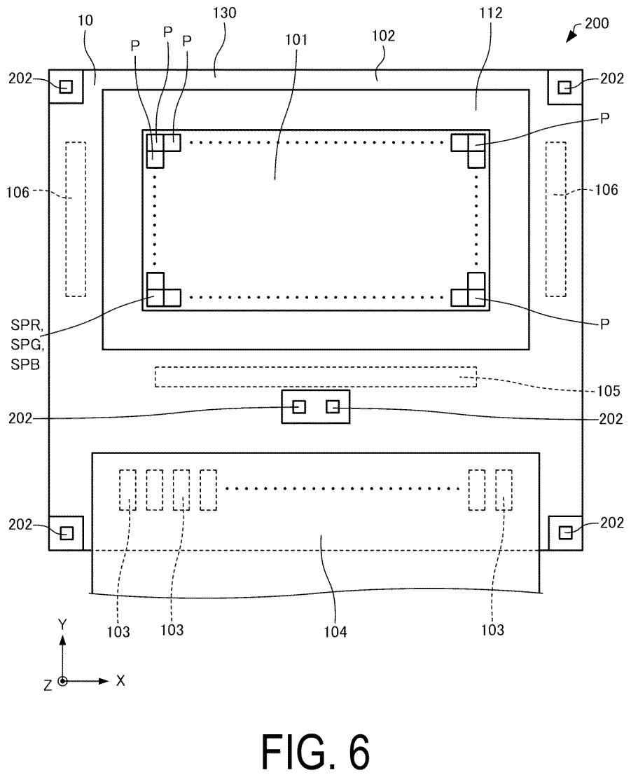

Next, a display device according to a modification example of the present embodiment is described with reference to the drawing. FIG. 6 is a plan view schematically illustrating a display device 200 according to the modification example of the present embodiment. In the following description, in the display device 200 according to the modification example of the present embodiment, members having the same functions as those of the constituent members of the display device 100 according to the present embodiment described above are denoted with the same reference symbols, and detailed description thereof is omitted.

As illustrated in FIG. 6, the display device 200 is different from the above-mentioned display device 100 in that the element substrate 10 includes an alignment mark 202.

For example, a plurality of alignment marks 202 are provided. In the illustrated example, six alignment marks 202 are provided. In plan view, the alignment mark 202 is provided at each of the four corners of the element substrate 10. In plan view, two alignment marks are provided between the display region 101 and the plurality of external coupling terminals 103. In the illustrated example, the shape of the alignment mark 202 is a square shape.

The material of the alignment mark 202 is metal, for example. The material of the alignment mark 202 may be the same as that of the pixel electrode 52 or the same as that of the counter electrode 56. The alignment mark 202 may be formed in the step of forming the pixel electrode 52, or may be formed in the step of forming the counter electrode 56. For example, the alignment mark 202 serves as an alignment mark in a scribing step of cutting out the element substrate 10 having a predetermined shape from a silicon wafer. Note that the alignment mark 202 may serve as an alignment mark in a step other than the scribing step.

The light-shielding layer 120 does not overlap with the alignment mark 202 in plan view. The wall portion 130 does not overlap with the alignment mark 202 in plan view. The light-shielding layer 120 and the wall portion 130 are provided to avoid the alignment mark 202.

In the display device 200, the element substrate 10 includes the alignment mark 202, the wall portion 130 and the light-shielding layer 120 do not overlap with the alignment mark 202 in plan view. Thus, in the display device 200, when alignment is performed based on the alignment mark 202 by using, for example, a camera (not illustrated) in a step of manufacturing the display device 200, reflection or absorption of the light by the wall portion 130 or the light-shielding layer 120 can be suppressed. With this, degradation in alignment accuracy can be suppressed.

### 3. Electronic Apparatus

### 3.1. Overall Configuration

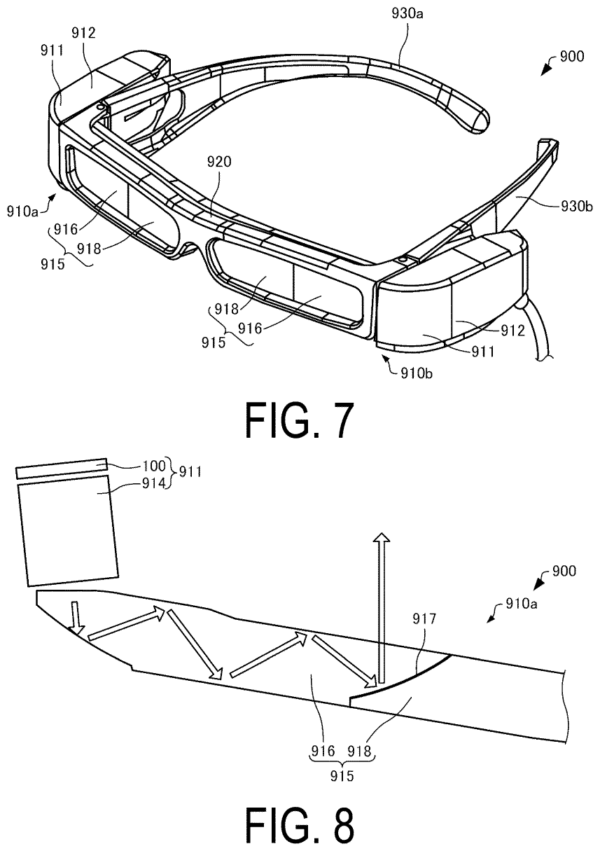

Next, a head-mounted display being an electronic apparatus according to the present embodiment is described with reference to the accompanying drawings. FIG. 7 is a perspective view schematically illustrating a head-mounted display 900 according to the present embodiment.

As illustrated in FIG. 7, the head-mounted display 900 is a head-mounted device that has an outer appearance of an eyewear. The head-mounted display 900 is mounted on the head of a viewer. The viewer is a user who uses the head-mounted display 900. The head-mounted display 900 allows the viewer to visually recognize image light of a virtual image and to visually recognize an external image in a see-through manner.

The head-mounted display 900 includes a first display unit 910a, a second display unit 910b, a frame 920, a first temple 930a, and a second temple 930b for example.

The first display unit 910a and the second display unit 910b display images. Specifically, the first display unit 910a displays a virtual image for the right eye of the viewer. The second display unit 910b displays a virtual image for the left eye of the viewer. The display units 910a and 910b include, for example, an image forming device 911 and a light-guiding device 915.

The image forming device 911 generates image light. The image forming device 911 includes, for example, an optical system such as a light source and a projection device, and an external member 912. The external member 912 houses the light source and the projection device.

The light-guiding device 915 covers the front of the eyes of the viewer. The light-guiding device 915 guides the image light formed by the image forming device 911 and allows the viewer to visually recognize external light and the image light in an overlapping manner. Note that details of the image forming device 911 and the light-guiding device 915 will be described below.

The frame 920 supports the first display unit 910a and the second display unit 910b. For example, the frame 920 surrounds the display units 910a and 910b. In the illustrated example, the image forming device 911 of the first display unit 910a is attached to one end portion of the frame 920. The image forming device 911 of the second display unit 910b is attached to the other end portion of the frame 920.

The first temple 930a and the second temple 930b extend from the frame 920. In the illustrated example, the first temple 930a extends from one end portion of the frame 920. The second temple 930b extends from the other end portion of the frame 920.

The first temple 930a and the second temple 930b are put on the ears of the viewer when the head-mounted display 900 is worn by the viewer. The head of the viewer is positioned between the temples 930a and 930b.

### 3.2. Image Forming Device and Light-Guiding Device

FIG. 8 is a diagram schematically illustrating the image forming device 911 and the light-guiding device 915 of the first display unit 910a of the head-mounted display 900. Note that the first display unit 910a and the second display unit 910b have basically the same configuration. Therefore, the following description on the first display unit 910a is applied to the second display unit 910b.

As illustrated in FIG. 8, for example, the image forming device 911 includes the display device 100 as a light source and a projection device 914 for image formation.

The projection device 914 projects the image light emitted from the display device 100 toward the light-guiding device 915. The projection device 914 is, for example, a projection lens. As the lens constituting the projection device 914, a lens having an axially symmetric surface as a lens surface may be used.

The light-guiding device 915 is accurately positioned with respect to the projection device 914 by being screwed to a lens barrel of the projection device 914, for example. The light-guiding device 915 includes, for example, an image light-guiding member 916 that guides the image light and a see-through member 918 for see-through view.

The image light emitted from the projection device 914 is incident on the image light-guiding member 916. The image light-guiding member 916 is a prism that guides the image light toward the eyes of the viewer. The image light incident on the image light-guiding member 916 is repeatedly reflected on the inner surface of the image light guide member 916, and then is reflected by a reflective layer 917 to be emitted from the image light-guiding member 916. The image light emitted from the image light-guiding member 916 reaches the eyes of the viewer. The reflective layer 917 is constituted by, for example, metal or a dielectric multilayer film. The reflective layer 917 may be a half mirror.

The see-through member 918 is adjacent to the image light-guiding member 916. The see-through member 918 is fixed to the image light-guiding member 916. The outer surface of the see-through member 918 is continuous with the outer surface of the image light-guiding member 916, for example. The viewer sees the external light through the see-through member 918. The image light-guiding member 916 also has the function of making the viewer see the external light therethrough, in addition to the function of guiding the image light. Note that the head-mounted display 900 may be configured so as not to allow the viewer to see the external light therethrough.

The electronic apparatus according to the present embodiment is not limited the head-mounted display as long as the display device according to the present embodiment is included. The electronic apparatus according to the present embodiment may be an electronic view finder (EVF), a projector, a wearable display such as a smart watch, or a vehicle head-up display.

The embodiment and the modification example that are described above are merely examples, and are not limited thereto. For example, the embodiment and the modification example can also be combined as appropriate.

The present disclosure includes configurations that are substantially identical to the configurations described in the embodiment, for example, configurations with identical functions, methods, and results, or with identical advantages and effects. Also, the present disclosure includes configurations obtained by replacing non-essential portions of the configurations described in the embodiment. In addition, the present disclosure includes configurations having the same operations and effects, or can achieve the same advantages as those of the configurations described in the embodiment. Further, the present disclosure includes configurations obtained by adding known techniques to the configurations described in the embodiment.

The following content is derived from the embodiment and the modification example that are described above.

A display device according to one aspect includes a first substrate, and a second substrate arranged facing the first substrate and having a light-transmitting property, wherein the first substrate includes a support substrate including a substrate surface being a surface at a side facing the second substrate, a plurality of light-emitting elements provided at the substrate surface side of the support substrate, a first color filter provided at the second substrate side of a first light-emitting element of the plurality of light-emitting elements, a second color filter provided at the second substrate side of a second light-emitting element of the plurality of light-emitting elements and having a color different from that of the first color filter, a light-shielding layer provided at the substrate surface side of the support substrate, surrounding the plurality of light-emitting elements in a plan view, and including a first layer made of the same material as that of the first color filter and a second layer made of the same material as that of the second color filter, and a wall portion provided at a side of the light-shielding layer opposite to the support substrate and surrounding the plurality of light-emitting elements in the plan view, an adhesive is provided at an inner side of the wall portion in the plan view, and the second substrate is bonded to the first substrate via the adhesive.

According to the display device, the adhesive is less likely to overflow from the wall portion. Therefore, a height difference of the second substrate can be reduced.

In the display device according to one aspect, the second substrate may be provided at the inner side of the wall portion in the plan view.

According to the display device, a height difference of the second substrate can be further reduced.

In the display device according to one aspect, an outer edge of the second substrate may include a first side in the plan view, and an inner edge of the wall portion may include a second side being parallel to the first side and facing the first side.

According to the display device, a height difference of the second substrate can be further reduced.

In the display device according to one aspect, the wall portion may have a light-transmitting property.

According to the display device, the light that is emitted from the light-emitting element and enters the wall portion can be transmitted to the outside of the wall portion.

In the display device according to one aspect, the wall portion may have a light-shielding property.

According to the display device, the light that is emitted from the light-emitting element and enters the wall portion can be absorbed at the wall portion.

In the display device according to one aspect, the first substrate may include an alignment mark, and the wall portion and the light-shielding layer may not overlap with the alignment mark in the plan view.

According to the display device, degradation in alignment accuracy can be suppressed.

In the display device according to one aspect, the first substrate may include a third color filter provided at the second substrate side of a third light-emitting element of the plurality of light-emitting elements and having a color different from those of the first color filter and the second color filter, and the light-shielding layer may include a third layer made of the same material as that of the third color filter.

According to the display device, the wall portion can be arranged at a higher position.

An electronic apparatus according to one aspect includes the display device according to one aspect.

What is claimed is:

1. A display device comprising:
a first substrate; and
a second substrate arranged facing the first substrate and having a light-transmitting property, wherein
the first substrate includes:
a support substrate including a substrate surface being a surface at a side facing the second substrate,
a plurality of light-emitting elements provided at a substrate surface side of the support substrate,
a first color filter provided at a second substrate side of a first light-emitting element of the plurality of light-emitting elements,
a second color filter provided at a second substrate side of a second light-emitting element of the plurality of light-emitting elements and having a color different from that of the first color filter,
a light-shielding layer provided at the substrate surface side of the support substrate, surrounding the plurality of light-emitting elements in a plan view, and including a first layer made of a same material as that of the first color filter and a second layer made of a same material as that of the second color filter, and
a wall portion provided at a side of the light-shielding layer opposite to the support substrate, and surrounding the plurality of light-emitting elements in the plan view,
an adhesive is provided at an inner side of the wall portion in the plan view, and
the second substrate is bonded to the first substrate via the adhesive.

2. The display device according to claim 1, wherein
the second substrate is provided at the inner side of the wall portion in the plan view.

3. The display device according to claim 2, wherein
an outer edge of the second substrate includes a first side in the plan view and
an inner edge of the wall portion includes a second side being parallel to the first side and facing the first side.

4. The display device according to claim 1, wherein
the wall portion has a light-transmitting property.

5. The display device according to claim 1, wherein
the wall portion has a light-shielding property.

6. The display device according to claim 1, wherein
the first substrate includes an alignment mark, and
the wall portion and the light-shielding layer do not overlap with the alignment mark in the plan view.

7. The display device according to claim 1, wherein
the first substrate includes a third color filter provided at a second substrate side of a third light-emitting element of the plurality of light-emitting elements and having a color different from those of the first color filter and the second color filter, and
the light-shielding layer includes a third layer made of a same material as that of the third color filter.

8. An electronic apparatus comprising the display device according to claim 1.
